(19) United States
(12) Patent Application Publication
(10) Pub. No.: US 2026/0109617 A1
(43) Pub. Date: Apr. 23, 2026

(54) SPHERICAL ALUMINA POWDER

(71) Applicant: Resonac Corporation, Tokyo (JP)

(72) Inventors: Hiroshi TSUZUKI, Tokyo (JP); Katsutoshi TAMURA, Tokyo (JP); Ryutaro NAGATA, Tokyo (JP); Motohiro ARIFUKU, Tokyo (JP); Daisuke MIYAMOTO, Tokyo (JP)

(73) Assignee: Resonac Corporation, Tokyo (JP)

(21) Appl. No.: 19/168,480

(22) PCT Filed: Feb. 5, 2025
(86) PCT No.: PCT/JP2025/003668

§ 371 Date: Sep. 24, 2025

(30) Foreign Application Priority Data
Mar. 28, 2024 (JP) 2024-054466

(51) Int. Cl. C01F 7/021; B32B 15/08; C08K 3/22; H10W 40/25; H10W 76/67

(52) U.S. Cl. CPC C01F 7/021; B32B 15/08; C08K 3/22; H10W 40/257; H10W 76/67; C01P 2004/32; C01P 2004/51; C01P 2004/61; C01P 2004/62; C01P 2006/12; C01P 2006/19; C08K 2003/2227; C08K 2201/005

(57) ABSTRACT

A spherical alumina powder, wherein D50 is 0.1 to 40 μm; a circularity is 0.90 or more and 1.00 or less; an α-phase percentage is 60% or more and 100% or less; and a particle surface roughness represented by Equation (1) below is 1.14 or more and 1.35 or less:

$$Particle surface roughness = BET specific surface area A / sphere - equivalent specific surface area Sa calculated from particle size distribution . \qquad Equation ( 1 )$$

### TECHNICAL FIELD

The present disclosure relates to a spherical alumina powder and a method for producing the same.

### BACKGROUND ART

In recent years, mobile devices, such as mobile phones, and electronic devices mounted on vehicles have been remarkably reduced in size, weight, and thickness. As a result, electronic components such as IC chips and memories mounted on printed wiring boards in electronic devices are being integrated at ever higher density, and the heat generation density in electronic devices tends to become higher. When the heat generation density in the electronic devices increases, the temperature rise accompanying the heat generation inside the electronic devices becomes significant, leading to a decrease in the operation performance and a decrease in the reliability of electronic components. Therefore, it is required to quickly transfer the heat generated from the electronic components to the outside and dissipate the heat. Therefore, there is a growing need to improve the thermal conductivity of package materials and substrate materials of the electronic devices.

In order to solve the above problems, the mainstream method is to fill an insulating resin material constituting a package material and a substrate material of an electronic device with an inorganic material powder having high thermal conductivity as a filler at a high filling percentage. As the inorganic material powder having high thermal conductivity, alumina, magnesia, boron nitride, aluminum nitride, and the like are known, and alumina powder is generally used in many cases from the viewpoint of chemical resistance, moisture absorption stability, and the like.

The shape of the inorganic material powder is preferably a spherical shape, which is easily kneaded with the resin at a high filling percentage. It is known that spherical alumina powder is generally produced by a so-called thermal spraying method, in which Bayer process alumina as a raw material is sprayed into a flame and rapidly cooled while being melted to be spheroidized.

The thermal spraying method is described in PTL 1.

However, in the known thermal spraying method, when the particle size is as large as about 50 μm, spherical alumina having a high content of α-alumina (hereinafter, a content of α-alumina is also referred to as α-phase percentage) is obtained, while there is a problem that the content of a low-temperature phase such as δ-alumina increases as the particle size decreases, and the thermal conductivity of the spherical alumina decreases. Therefore, it has been studied to increase the α-phase percentage by subjecting spherical alumina to a heat treatment (PTL 2).

### CITATION LIST

### Patent Document

PTL 1: JP H11-147711 A
PTL 2: JP 2014-9140 A

### SUMMARY OF INVENTION

### Technical Problem

When the α-phase percentage is increased by subjecting the spherical alumina to a heat treatment, the surface roughness of the spherical alumina is increased by the heat treatment, and the kneadability into the resin is decreased. Therefore, there is a problem that the thermal conductivity of the resin material filled with the spherical alumina is not high. On the other hand, known spherical alumina is excellent in filling properties and fluidity, and therefore, it is likely to settle in the resin composition kneaded and filled, and may undergo segregation, forming a resin layer having a lower thermal conductivity and a close-packed layer of spherical alumina powder. This causes a further decrease in thermal conductivity and a variation in performance.

The present disclosure provides a spherical alumina powder capable of providing a resin composition having a high thermal conductivity even when the spherical alumina powder has a D50 of 0.1 to 40 μm. The present disclosure further provides a resin composition comprising the spherical alumina powder, and a prepreg.

### Solution to Problem

The content of the present disclosure relates to the following matters.

[1]

A spherical alumina powder, wherein
D50 is 0.1 to 40 μm;
a circularity is 0.90 or more and 1.00 or less;
an α-phase percentage is 60% or more and 100% or less; and
a particle surface roughness represented by Equation (1) below is 1.14 or more and 1.35 or less:

$$Particle surface roughness = BET specific surface area A / sphere - equivalent specific surface area Sa calculated from particle size distribution . \qquad Equation ( 1 )$$

[2]

The spherical alumina powder according to aspect [1], wherein a specific gravity is 3.80 g/cm³ or more.

[3]

The spherical alumina powder according to aspect [1] or [2], wherein a BET specific surface area A is 0.1 or more and 2.0 or less.

[4]

The spherical alumina powder according to any one of aspects [1] to [3], wherein an oil absorption percentage is 30% or more and 50% or less.

[5]

A resin composition comprising the spherical alumina powder according to any one of aspects [1] to [4] and a resin.

[6]

A prepreg comprising a substrate impregnated with the resin composition according to aspect [5]

[7]

A cured product of the prepreg according to aspect [6] or a laminate thereof.

[8]

A metal-clad laminate comprising:
the cured product according to aspect [7]; and
a metal foil disposed on at least one main surface of the cured product.
   [9]

The resin composition according to aspect [5], which is used as a sealing material for an electronic component device.

[10]

An electronic component device comprising an element and a cured product of the resin composition according to aspect [5], the cured product sealing the element.

[6]

A method for producing a spherical alumina powder, comprising:
a high-temperature step of forming a high-temperature region inside a furnace with a burner that forms a flame;
a spheroidizing step of charging a raw material alumina powder into the furnace and heating and melting the raw material alumina powder to produce a spherical alumina powder before heat treatment;
a cooling and washing step of charging the spherical alumina powder before heat treatment into cooling washing water in a water tank to cool and wash the spherical alumina powder before heat treatment;
a recovery step of separating the spherical alumina powder before heat treatment and the cooling washing water from each other to recover the spherical alumina powder before heat treatment; and
a heat treatment step of heat-treating the recovered spherical alumina powder before heat treatment at 1100 to 1300° C. in an air atmosphere to obtain a spherical alumina powder.

### Advantageous Effects of Invention

According to the present disclosure, a spherical alumina powder capable of providing a resin composition having a high thermal conductivity even when the spherical alumina powder has a D50 of 0.1 to 40 μm can be provided. Furthermore, according to the present disclosure, a resin composition comprising the spherical alumina powder, and a prepreg can be provided.

### BRIEF DESCRIPTION OF DRAWINGS

FIG. 1 is a diagram illustrating a process flow of a method for producing a spherical alumina powder before heat treatment according to one embodiment.

FIG. 2 is a schematic view illustrating the configuration of a production apparatus applicable to the process flow of FIG. 1.

### DESCRIPTION OF EMBODIMENTS

Hereinafter, embodiments of the present invention will be described in detail. The embodiments described below are representative examples of the present invention, and the present invention is not limited to these embodiments.

In the present specification, when a plurality of upper limits or lower limits are listed, numerical ranges can be formed from all combinations of upper limits and lower limits. Similarly, where a plurality of numerical ranges are listed, upper limits and lower limits can be separately selected and combined from the numerical ranges to form separate numerical ranges.

### [Spherical Alumina Powder]

The spherical alumina powder in one embodiment has D50 of 0.1 to 40 μm, a circularity of 0.90 or more and 1.00 or less, an α-phase percentage of 60% or more and 100% or less, and a particle surface roughness represented by Equation (1) below of 1.14 or more and 1.35 or less.

$$Particle surface roughness = BET specific surface area A / sphere - equivalent specific surface area Sa calculated from particle size distribution \qquad Equation ( 1 )$$

The spherical alumina powder has a high α-phase percentage and a particle surface roughness within an appropriate range from the viewpoint of filling properties, and therefore has a high thermal conductivity of itself, is less likely to cause segregation in the resin composition, and is likely to uniformly form contact points of particles. Therefore, the spherical alumina powder can provide a resin composition having a high thermal conductivity.

### (D50)

The D50 of the spherical alumina powder is 0.1 μm or more, preferably 0.5 μm or more, and more preferably 1.0 μm or more. The D50 of the spherical alumina powder is 40 μm or less, preferably 10 μm or less, and more preferably 5.0 μm or less. When the D50 is 0.1 μm or more, the thermal conductivity can be increased. When the D50 is 40 μm or less, the filling properties into the resin can be enhanced.

The D50 refers to a 50% particle size in a volume-based cumulative particle size distribution measured using a laser diffraction-scattering particle size analyzer, and is measured by the method described in the section of Examples.

### (α-Phase Percentage)

The α-phase percentage of the spherical alumina powder is 60% or more, preferably 70% or more, and more preferably 80% or more. The higher the α-phase percentage, the more improvement in thermal conductivity can be expected. The α-phase percentage of the spherical alumina powder is 100% or less, and may be 99% or less, or 98% or less.

The α-phase percentage is calculated according to Equation (2) below, wherein X is the maximum peak intensity at a diffraction angle 2θ=35.2°±0.2° of the α-alumina crystal phase in X-ray diffraction measurement, and Y is the maximum peak intensity at a diffraction angle 2θ=67.3°±0.2° of the crystal phase other than α-alumina.

$$α - phase percentage = ( X / ( X + Y ) ) \times 100 ( \% ) \qquad Equation ( 2 )$$

### (Particle Surface Roughness A/Sa)

In the present specification, the particle surface roughness refers to a value calculated according to Equation (1) below.

$$Particle surface roughness = BET specific surface area A / sphere - equivalent specific surface area Sa calculated from particle size distribution \qquad Equation ( 1 )$$

The spherical alumina powder has a particle surface roughness of 1.14 or more, preferably 1.16 or more, and more preferably 1.20 or more. The spherical alumina has a particle surface roughness of 1.35 or less, preferably 1.31 or less, and more preferably 1.29 or less. When the particle surface roughness is 1.14 or more, sedimentation of alumina particles in the resin composition is suppressed. When the particle surface roughness is 1.35 or less, the filling properties into the resin can be enhanced.

### (BET Specific Surface Area A)

The BET specific surface area A of the spherical alumina powder is preferably 0.1 or more, more preferably 0.5 or more, and still more preferably 1.0 or more. The BET specific surface area A of the spherical alumina powder is preferably 2.0 or less, more preferably 1.7 or less, and still more preferably 1.5 or less. When the BET specific surface area A is 0.1 or more, the heat dissipation property is excellent. When the BET specific surface area A is 2.0 or less, the filling properties into the resin can be enhanced.

In the present specification, the BET specific surface area A is a value measured and calculated according to “6.2 Flow method (3.5), Single point method” in JIS R 1626:1996 (Measuring method for the specific surface area of fine ceramic powders by gas adsorption using the BET method). The measurement is performed by subjecting the sample to heating to 180° C. and nitrogen gas flow for 20 minutes, as pretreatment, and then using nitrogen gas as an adsorbate. (Sphere-Equivalent Specific Surface Area Sa Calculated from Particle Size Distribution) In the present specification, the sphere-equivalent specific surface area Sa calculated from the particle size distribution (also referred to as sphere-equivalent specific surface area Sa) is determined by the method described in the section of Examples.

The spherical alumina powder preferably has a sphere-equivalent specific surface area Sa of 0.1 or more, more preferably 0.5 or more, and still more preferably 1.0 or more. The spherical alumina powder has a sphere-equivalent specific surface area Sa of preferably 2.0 or less, more preferably 1.7 or less, and still more preferably 1.5 or less. When the sphere-equivalent specific surface area Sa is 0.1 or more, the heat dissipation property is excellent. When the sphere-equivalent specific surface area Sa is 2.0 or less, the filling properties into the resin can be enhanced.

### (Specific Gravity)

The specific gravity of the spherical alumina powder is preferably 3.80 g/cm³ or more, and more preferably 3.85 g/cm³ or more. The specific gravity of the spherical alumina powder is preferably 4.00 g/cm³ or less, and more preferably 3.97 g/cm³ or less. When the specific gravity is 3.80 g/cm³ or more, the content ratio of α-alumina is large, and the thermal conductivity is excellent. The specific gravity is determined by the method described in the section of Examples.

### (Circularity)

The circularity of the spherical alumina powder is 0.90 or more, preferably 0.92 or more, more preferably 0.93 or more, and still more preferably 0.95 or more. The circularity of the spherical alumina powder is 1.00 or less by definition, but may be 0.99 or less from the viewpoint of productivity. The circularity is measured by the method described in the section of Examples.

### (Oil Absorption Percentage)

The oil absorption percentage of the spherical alumina powder is preferably 30% or more, more preferably 35% or more, and still more preferably 38% or more. The oil absorption percentage of the spherical alumina powder is preferably 50% or less, more preferably 45% or less, and still more preferably 43% or less. When the oil absorption percentage is 30% or more, the sedimentation of alumina particles in the resin composition is suppressed. When the oil absorption percentage is 50% or less, the filling properties into the resin can be enhanced. The oil absorption percentage is measured by the method described in the section of Examples.

### [Method for Producing Spherical Alumina Powder]

In a general flame melting method, spherical alumina powders are produced by a known method in which a raw material powder that can be an aluminum source such as an aluminum oxide powder, an aluminum hydroxide powder, or a metal aluminum powder is charged into a high-temperature flame, the raw material powder is melted to spheroidize by surface tension, and then cooled to a collectable temperature by air cooling, and the powder is collected with a collection device. In such a method, since cooling after melting is performed slowly, crystallization of alumina particles proceeds in the cooling process, and the particle surface roughness increases. In addition, since the temperature profile from the spheroidization to the cooling is not controlled, the degree of progress of crystallization in the cooling process varies. Therefore, when such a known spherical alumina powder is subjected to a heat treatment, it is difficult to control the α-phase percentage and the particle surface roughness to desired ranges.

On the other hand, the present inventors have found that a spherical alumina powder having an α-phase percentage and a particle surface roughness controlled to desired ranges can be obtained by spheroidizing a raw material powder by the above-described known method, immediately cooling the powder in a high temperature state in a water tank, and subjecting the spherical alumina powder, from which impurities such as a sodium component and a calcium component exuding from the inside of the particles to the surface and possibly inducing particle fusion and sintering are washed, to a heat treatment. Hereinafter, the spherical alumina powder before the heat treatment is referred to as a spherical alumina powder before heat treatment, the spherical alumina powder after the heat treatment is referred to as a spherical alumina powder, and an exemplary method for producing them is described.

### (Method for Producing Spherical Alumina Powder Before Heat Treatment)

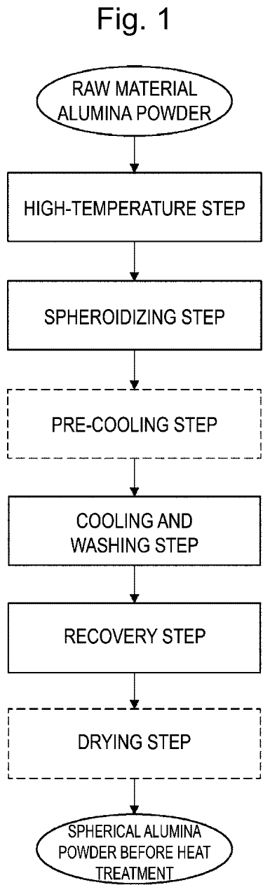

A method for producing a spherical alumina powder before heat treatment according to one embodiment includes: a high-temperature step of forming a high-temperature region inside a furnace with a burner that forms a flame; a spheroidizing step of charging a raw material alumina powder into the furnace and heating and melting the raw material alumina powder to produce a spherical alumina powder before heat treatment; a cooling and washing step of charging the spherical alumina powder before heat treatment into cooling washing water in a water tank to cool and wash the spherical alumina powder before heat treatment; and a recovery step of separating the spherical alumina powder before heat treatment and the cooling washing water from each other to recover the spherical alumina powder before heat treatment. FIG. 1 shows a process flow of a method for producing a spherical alumina powder before heat treatment according to one embodiment. By simultaneously cooling and washing the spherical alumina powder before heat treatment, it is possible to produce the spherical alumina powder before heat treatment in which the amount of Na and other ionic impurities present on the particle surface and having a possibility of inducing particle fusion and sintering is reduced at low cost and in a short time.

### <Raw Material Alumina Powder>

The raw material alumina powder is not particularly limited, and it is preferable to use a raw material alumina powder having a small amount of Na. Specific examples of the alumina powder having a small amount of Na include a low-sodium alumina powder produced by the Bayer process.

The shape of the raw material alumina powder is not limited, and is preferably non-spherical for the purpose of obtaining a spherical alumina powder before heat treatment. The circularity of the raw material alumina powder is, for example, less than 0.90, 0.86 or less, or 0.84 or less.

The D50 of the raw material alumina powder is preferably 0.1 μm or more and 40 μm or less from the viewpoint of obtaining a spherical alumina powder before heat treatment having a size suitable for a heat dissipation filler. From the same viewpoint, the D50 is more preferably 0.5 μm or more and 10 μm or less, and still more preferably 1.0 μm or more and 5 μm or less.

### <Furnace>

Examples of the furnace include a vertical furnace and a horizontal furnace. The shape of the furnace is not limited, and examples thereof include a cylindrical shape and a polygonal prism shape such as a hexagonal prism shape. The cylindrical shape is preferable because the temperature in the furnace can be easily controlled to be uniform. The cylindrical shape means that at least a part of the furnace is cylindrical, and may include a part having another shape. The polygonal prism shape means that at least a part of the furnace is polygonal prismatic, and may include a part having another shape. From the viewpoint of increasing the collection performance, the downstream portion of the furnace preferably has an inverted conical shape in which the discharge hole side is narrowed.

The material of the furnace is not limited, and the inner wall is preferably made of stainless steel from the viewpoint of reducing contamination of the spherical alumina powder before heat treatment with impurities. A water-cooled jacket may be provided around the outer periphery of the furnace to cool the furnace.

### <High-Temperature Step>

The high-temperature step is a step of forming a high-temperature region inside the furnace with a burner that forms a flame.

The burner is a device that mixes an appropriate amount of a combustion-supporting gas with a combustible gas to form a flame in a furnace. The combustible gas is supplied from a combustible gas supply source to the burner, and the combustion-supporting gas is supplied from a combustion-supporting gas supply source to the burner. Examples of the combustible gas include liquefied natural gas (LNG) and liquefied petroleum gas (LPG). Examples of the combustion-supporting gas include air, oxygen gas, and oxygen-enriched air.

The temperature in the high-temperature region is preferably 2100° C. or more. The temperature in the high-temperature region is preferably 2500° C. or less, and more preferably 2300° C. or less. When the temperature is 2100° C. or more, the temperature is the melting point of alumina or more, and therefore, the circularity of the alumina powder to be obtained is easily increased. When the temperature is 2500° C. or less, the temperature is within the range of heat resistance of a general burner, and therefore, it is advantageous in terms of cost.

### <Spheroidizing Step>

The spheroidizing step is a step of charging a raw material alumina powder into the furnace and heating and melting the raw material alumina powder to produce a spherical alumina powder before heat treatment. In the spheroidizing step, a carrier gas for supplying the raw material alumina powder may be used as necessary. Examples of the carrier gas include at least one selected from air, nitrogen, oxygen, and carbon dioxide.

### <Pre-Cooling Step>

The method for producing the spherical alumina powder before heat treatment preferably includes a pre-cooling step of pre-cooling the spherical alumina powder before heat treatment. The pre-cooling step is performed after the spheroidizing step and before the cooling and washing step. The equipment for performing the pre-cooling is preferably provided outside the high-temperature region of the furnace or between the furnace and the water tank used in the cooling and washing step. As a result, the spherical alumina powder before heat treatment to be charged into the cooling washing water in the water tank in the cooling and washing step can be cooled to a preferable temperature in a short time.

The pre-cooling is preferably performed by spraying water to the spherical alumina powder before heat treatment. Examples of the equipment for spraying water include a shower.

### <Cooling and Washing Step>

The cooling and washing step is a step of charging the spherical alumina powder before heat treatment into cooling washing water in a water tank to simultaneously perform cooling and washing of the spherical alumina powder before heat treatment. By performing cooling and washing at the same time, the equipment can be made small-scale and the overall process time can be shortened, as compared with the case where cooling and washing are performed as separate steps, for example, the case where the spherical alumina powder before heat treatment is recovered by a collector such as a cyclone while being air-cooled after the spheroidizing step, and the recovered spherical alumina powder before heat treatment is washed. In addition, variation in degree of crystallinity can be suppressed. The method for producing a spherical alumina powder before heat treatment enables the production of a spherical alumina powder before heat treatment having a low BET specific surface area because of a small thermal history.

The water tank stores cooling washing water for washing the spherical alumina powder before heat treatment while cooling the same. In order to increase the washing efficiency, it is preferable to stir the cooling washing water with an agitator. The cooling washing water is not limited, and examples thereof include city water.

The temperature of the cooling washing water is preferably 50° C. or more, and more preferably 70° C. or more, from the viewpoint of efficiently reducing the ionic impurities present on the surface of the spherical alumina powder before heat treatment. From the viewpoint of suppressing damage to the furnace body of the furnace due to a heat load, the temperature of the cooling washing water is preferably 80° C. or less.

In the cooling and washing step, the spherical alumina powder before heat treatment is preferably charged into the cooling washing water within 5 seconds after leaving the furnace. By charging the spherical alumina powder before heat treatment within 5 seconds, the BET specific surface area of the spherical alumina powder before heat treatment can be suppressed to a low level. By charging the spherical alumina powder before heat treatment within 5 seconds, it is possible to suppress the variation in degree of crystallinity of the spherical alumina powder before heat treatment.

In the cooling and washing step, the temperature of the spherical alumina powder before heat treatment to be charged into the cooling washing water is preferably 200° C. or less, and more preferably 100° C. or less. More preferably, the temperature of the spherical alumina powder before heat treatment from the time when the powder is discharged from the furnace to the time when the powder is charged into the cooling washing water is 200° C. or less, and particularly preferably 100° C. or less. When the temperature is 200° C. or less, there is little possibility that the cooling washing water in the water tank is overheated and evaporated, and therefore, stable production is facilitated.

The temperature of the spherical alumina powder before heat treatment can be determined by simulation software Ansys Fluent (Ansys Inc.).

### <Recovery Step>

The recovery step is a step of separating the spherical alumina powder before heat treatment and the cooling washing water from each other to recover the spherical alumina powder before heat treatment. The recovery method is not limited, and examples thereof include a method of settling the spherical alumina powder before heat treatment dispersed in the cooling washing water and removing the supernatant water with a pump or the like. This method is preferable because ionic impurities such as Na⁺ and Ca²⁺ attached to the particle surface can be washed and removed.

### <Drying Step>

The method for producing the spherical alumina powder before heat treatment preferably includes a drying step. The drying step is a step of drying the spherical alumina powder before heat treatment from which the cooling washing water has been separated. In the drying step, the moisture remaining after the recovery step is removed. The drying method is not limited, and may be air drying or heat drying.

### <Apparatus for Producing Spherical Alumina Powder Before Heat Treatment>

Hereinafter, a preferred embodiment of a production apparatus used in the method for producing a spherical alumina powder before heat treatment of one embodiment and a configuration thereof will be described in detail with reference to the drawings. In the drawings used in the following description, for the sake of convenience, characteristic portions are focused on and illustrated in order to make the characteristics easy to understand, and the dimensional ratios of the respective components are not necessarily the same as those of the actual device.

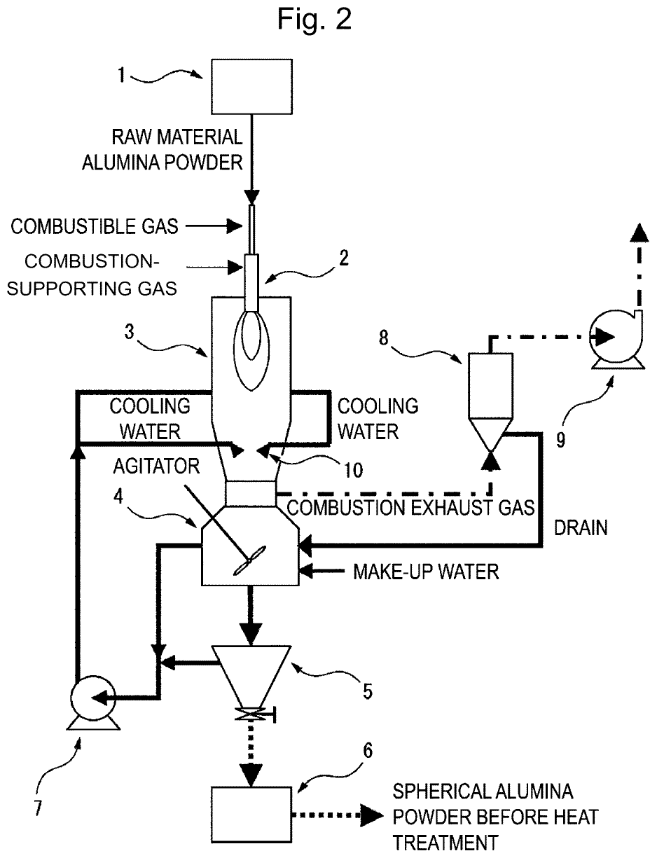

The apparatus for producing a spherical alumina powder before heat treatment will be described with reference to FIG. 2. As shown in FIG. 2, the apparatus for producing a spherical alumina powder before heat treatment is schematically configured to include a hopper 1 for storing and charging raw materials, a spheroidizing burner 2, a water-cooled jacket-type spheroidizing furnace 3 (also referred to as a spheroidizing furnace 3) for spheroidizing, an agitated cooling tank 4 for washing and cooling the spherical alumina powder before heat treatment, a separation tank 5 for separating the collected spherical alumina powder before heat treatment from a large amount of water and taking out the spherical alumina powder before heat treatment, and a drying device 6 for drying the spherical alumina powder before heat treatment in which water remains to obtain the spherical alumina powder before heat treatment as a dry powder.

A feeder device or the like is attached to the hopper 1 for the raw material, and the raw material alumina powder can be quantitatively supplied to the spheroidizing burner 2. The spheroidizing burner 2 feeds the raw material alumina powder fed from hopper 1 for the raw material into the spheroidizing furnace 3. The raw material alumina powder may be supplied to the spheroidizing burner 2 using a carrier gas for powder conveyance.

The spheroidizing burner 2 is provided in the spheroidizing furnace 3. The spheroidizing burner 2 is supplied with a combustible gas from a combustible gas supply source (not shown) and a combustion-supporting gas from a combustion-supporting gas supply source (not shown), and the spheroidizing burner 2 can form a flame in the spheroidizing furnace 3.

The spheroidizing furnace 3 is a cylindrical vertical furnace, and the lower portion of the furnace has an inverted conical shape that narrows toward the discharge hole side. In the spheroidizing furnace 3, the raw material alumina powder charged into the high-temperature region formed by the flame is heated and melted, whereby the spherical alumina powder before heat treatment is produced.

A shower 10 is provided inside the spheroidizing furnace 3. The spherical alumina powder before heat treatment can be pre-cooled by spraying water to the spherical alumina powder before heat treatment exiting the high-temperature region with the shower 10. Although the shower is provided in the spheroidizing furnace 3 in FIG. 2, the shower may be provided at any position as long as the shower is on a path from when the spherical alumina powder before heat treatment exits the high-temperature region to when the spherical alumina powder before heat treatment comes into contact with the cooling washing water.

The spheroidizing furnace 3 is connected to the agitated cooling tank 4 via a short pipe. The short pipe is provided with a duct or the like, and the duct is connected to a scrubber-type collection device 8 and an exhaust device 9 so that the combustion exhaust gas can be discharged to the outside of the system. Since the combustion exhaust gas contains fine spherical alumina powder before heat treatment, it is desirable to pass the combustion exhaust gas through the scrubber-type collection device 8 to separate and remove the fine powder from the gas, and then discharge the cleaned combustion exhaust gas through an exhaust device 9. In FIG. 2, there is no gap between the spheroidizing furnace 3, the short pipe, and the agitated cooling tank 4, but there may be a gap therebetween.

In the agitated cooling tank 4, cooling washing water for cooling and washing the spherical alumina powder before heat treatment is stored. The cooling washing water in the agitated cooling tank 4 is agitated by an agitator to enhance the washing efficiency. A cooling water pump 7 is connected to the agitated cooling tank 4, and the cooling water pump 7 is connected to the shower 10 and is piped so that the cooling washing water in the tank can be circulated and used.

The separation tank 5 for separating the collected spherical alumina powder before heat treatment and the cooling washing water is connected to the agitated cooling tank 4, and a slurry containing the spherical alumina powder before heat treatment is supplied from the agitated cooling tank 4 to the separation tank 5. In the separation tank 5, the cooling washing water and the solid matter are separated, and the water is returned to the system through the cooling water pump 7 and circulated. At this time, ionic impurities such as Na attached to the particle surface are washed and removed. The solid matter is supplied to a drying device 6, and the remaining moisture attached thereto is dried, whereby a spherical alumina powder before heat treatment with less ionic impurities can be obtained.

According to this production apparatus, it is not necessary to install an expensive and large-scale apparatus such as an ion exchange water apparatus, and a spherical alumina powder before heat treatment having a small amount of ionic impurities can be obtained by a small-scale spheroidizing facility.

### (Method for Producing Spherical Alumina Powder)

The spherical alumina powder can be obtained by heat-treating the spherical alumina powder before heat treatment at 1100 to 1300° C. in an air atmosphere. By performing the heat treatment at 1100° C. or more, it is possible to promote the transition from a phase, which has a low thermal conductivity, other than the α crystal phase, for example, an amorphous phase, a γ crystal phase, a δ crystal phase, a θ crystal phase, or the like to the α crystal phase having a high thermal conductivity. By performing the heat treatment at 1300° C. or less, the surface roughness can be suppressed. By performing the heat treatment at 1300° C. or less, it is possible to suppress an increase in particle diameter due to fusion of particles.

The heat treatment time is preferably 1 hour or more, and more preferably 1 hour or more and 4 hours or less. When the time is 1 hour or more, the time for transition to the target α crystal phase is sufficient, and the target α-phase percentage is easily reached. When the time is 4 hours or less, sintering of the particles is suppressed, and a powder having a target particle size is easily obtained.

The heat treatment apparatus may be a general apparatus, and specific examples thereof include a truck furnace, a tunnel furnace, and a rotary kiln furnace. The heat treatment atmosphere is not particularly limited, and is preferably an air atmosphere.

The method for producing a spherical alumina powder may include a crushing step of crushing aggregated particles generated by the heat treatment, as necessary. The method for producing a spherical alumina powder may include a classification step of performing a classification treatment, as necessary. The heat treatment may cause aggregated particles in which some particles are sintered with each other. In this case, it is preferable to perform at least one treatment selected from a crushing treatment and a classification treatment. The crushing treatment may be performed by a wet method or a dry method. Examples of the crushing treatment include methods using a roll mill, a ball mill, a small-diameter ball mill (also referred to as a bead mill), a pot mill, a media stirring mill, an air flow pulverizer, a mortar, an automatic kneading mortar, a tank disintegrator, or a jet mill.

The spherical alumina powder is preferably used for applications requiring high thermal conductivity. The spherical alumina powder can be used as a filler in a material requiring high thermal conductivity, such as a heat dissipation material or a semiconductor sealing material.

### [Resin Composition]

The resin composition of one embodiment contains a spherical alumina powder and a resin. The resin composition can be used as a heat dissipating insulating resin composition or a sealing material, for example, a sealing material for an electronic component device. The resin composition is suitable for a semiconductor package and a printed wiring board requiring high thermal conductivity.

Examples of the resin include thermosetting resins and thermoplastic resins, and thermosetting resins are preferred. Examples of the thermosetting resin include amino resins such as epoxy resins, phenol resins, unsaturated imide resins, and melamine resins, unsaturated polyester resins, allyl resins, dicyclopentadiene resins, silicone resins, and triazine resins. Among them, an epoxy resin is preferable, since it is excellent in moldability and electrical insulation. The resin may be used singly or in combination of two or more types thereof.

Examples of the epoxy resin include a bisphenol A type epoxy resin, a bisphenol F type epoxy resin, a bisphenol S type epoxy resin, a biphenyl type epoxy resin, an alicyclic epoxy resin, a phenol novolac type epoxy resin, a cresol novolac type epoxy resin, a bisphenol A novolac type epoxy resin, a bisphenol F novolac type epoxy resin, a dicyclopentadiene type epoxy resin, a naphthalene type epoxy resin, and an anthracene type epoxy resin.

Examples of the thermoplastic resin include polyethylene, polypropylene, polystyrene, polyphenylene ether resin, phenoxy resin, polycarbonate resin, polyester resin, polyamide resin, polyamide-imide resin, polyimide resin, xylene resin, polyphenylene sulfide resin, polyetherimide resin, polyether ether ketone resin, and polyetherimide resin.

The content of the spherical alumina powder in the resin composition is preferably 50 to 90% by volume, and more preferably 60 to 85% by volume. When the content is 50% by volume or more, the spherical alumina powder exhibits a sufficient effect in enhancing thermal conductivity. When the content is 90% by volume or less, the resin composition has good moldability.

The resin composition may contain an inorganic filler other than the spherical alumina. Examples of the other inorganic fillers include aluminum hydroxide, zinc oxide, magnesium oxide, magnesium carbonate, magnesium hydroxide, titanium oxide, silicon oxide, and boron nitride. Among these, at least one selected from aluminum hydroxide, zinc oxide, magnesium oxide, and boron nitride is preferable from the viewpoint of enhancing thermal conductivity.

The resin composition may contain optional components other than the above components. Examples of the optional components include a curing agent, a curing accelerator, a flame retardant, an ultraviolet absorber, an antioxidant, an organic solvent, and a surface treatment agent.

Examples of the curing agent include, in the case of using an epoxy resin, polyfunctional phenol compounds such as phenol novolac and cresol novolac; amine compounds such as dicyandiamide, diaminodiphenylmethane, and diaminodiphenylsulfone; and acid anhydrides such as phthalic anhydride, pyromellitic anhydride, maleic anhydride, and maleic anhydride. The curing agent may be used singly or in combination of two or more types thereof.

Examples of the curing accelerator include, in the case of using an epoxy resin, an imidazole compound and a derivative thereof; an organophosphorus compound; a secondary amine; a tertiary amine; and a quaternary ammonium salt.

Examples of the imidazole compound and the derivative thereof include imidazole, 2-methylimidazole, 2-ethylimidazole, 2-ethyl-4-methylimidazole, 2-phenylimidazole, 2-undecylimidazole, 1-benzyl-2-methylimidazole, 2-heptadecylimidazole, 4,5-diphenylimidazole, 2-methylimidazoline, 2-phenylimidazoline, 2-undecylimidazoline, 2-heptadecylimidazoline, 2-isopropylimidazole, 2,4-dimethylimidazole, 2-phenyl-4-methylimidazole, 2-ethylimidazoline, 2-isopropylimidazoline, 2,4-dimethylimidazoline, and 2-phenyl-4-methylimidazoline. The imidazole compound and the derivative thereof may be masked with a masking agent. Examples of the masking agent include acrylonitrile, phenylene diisocyanate, toluidine isocyanate, naphthalene diisocyanate, methylene bisphenyl isocyanate, and melamine acrylate.

Examples of the organophosphorus compound include ethylenephosphine, propylphosphine, butylphosphine, phenylphosphine, trimethylphosphine, triethylphosphine, tributylphosphine, trioctylphosphine, triphenylphosphine, tricyclohexylphosphine, a triphenylphosphine/triphenylborane complex, and tetraphenylphosphonium tetraphenylborate.

Examples of the secondary amine include morpholine, piperidine, pyrrolidine, dimethylamine, diethylamine, dicyclohexylamine, N-alkylarylamine, piperazine, diallylamine, thiazoline, and thiomorpholine.

Examples of the tertiary amine include benzyldimethylamine, 2-(dimethylaminomethyl) phenol, and 2,4,6-tris(dimethylaminomethyl) phenol.

Examples of the quaternary ammonium salt include tetrabutylammonium iodide, tetrabutylammonium bromide, tetrabutylammonium chloride, tetrabutylammonium fluoride, benzalkonium chloride, benzyldi(2-hydroxyethyl)ethylammonium chloride, and decyldi(2-hydroxyethyl)methylammonium bromide.

The curing accelerator may be used singly or in combination of two or more types thereof.

The organic solvent can be used for the purpose of, for example, adjusting the viscosity of the resin composition. For example, when a prepreg is produced by impregnating a substrate with a resin composition, when a resin composition is applied, and the like, it is preferable to set the viscosity of the resin composition to an appropriate range using an organic solvent. The organic solvent may be removed after the impregnation or coating process.

Examples of the organic solvent include alcohols such as methanol, ethanol, propanol, and butanol; glycol ethers such as 2-methoxy ethanol, ethyleneglycol monobutyl ether, and propylene glycol monomethyl ether; ketones such as acetone, methyl ethyl ketone, methyl isobutyl ketone, and cyclohexanone; esters such as butyl acetate and propylene glycol monomethyl ether acetate; ethers such as tetrahydrofuran; aromatic hydrocarbons such as toluene and xylene; nitrogen atom-containing solvents such as dimethylformamide, dimethylacetamide, and N-methylpyrrolidone; and sulfur atom-containing solvents such as dimethyl sulfoxide. The organic solvent may be used singly or in combination of two or more types thereof.

Among these, methyl isobutyl ketone, methyl ethyl ketone, propylene glycol monomethyl ether, and 2-methoxy ethanol are preferable from the viewpoint of solubility, and methyl isobutyl ketone and propylene glycol monomethyl ether are more preferable from the viewpoint of low toxicity.

When the spherical alumina powder is dispersed in an organic solvent, a disperser such as a bead mill, a homogenizer, or a jet mill can be used for improving dispersibility. It is also preferable to pretreat the spherical alumina powder with a surface treatment agent described later or to perform integral blend treatment.

Examples of the surface treatment agent include coupling agents such as a silane coupling agent and a titanate coupling agent, and silicone oligomers. The spherical alumina powder may be pretreated with a surface treatment agent.

In the case of producing a prepreg by impregnating a substrate with the resin composition, the total content of components (also referred to as solid content) other than the organic solvent in the resin composition is preferably from 40 to 90 mass %, and more preferably from 50 to 85 mass %, with respect to the entire resin composition.

### [Method for Producing Resin Composition]

The method for producing the resin composition is not particularly limited. Examples of the method for producing the resin composition include a method in which components in a predetermined blending amount are sufficiently mixed by a mixer or the like, kneaded by a mixing roll, an extruder, or the like, and cooled. More specifically, a method of agitating and mixing the components in predetermined blending amounts, kneading the mixture with a kneader, a roll, an extruder, or the like heated to 70 to 140° C. in advance, and cooling the mixture is exemplified.

### [Prepreg]

A prepreg of one embodiment comprises a substrate impregnated with the resin composition.

Examples of the material of the substrate include inorganic fibers such as E glass, D glass, S glass, and Q glass. Examples of the form of the substrate include a woven fabric, a nonwoven fabric, a roving, a chopped strand mat, and a surfacing mat. The material and form of the substrate are selected depending on the intended use and performance, and one type of material or two or more types of materials and forms in combination may be used as necessary. From the viewpoint of heat resistance, moisture resistance, and processability, the substrate may be surface-treated. Examples of the surface treatment include a surface treatment with a silane coupling agent or the like and a mechanical opening treatment. The thickness of the substrate is, for example, 0.01 to 0.2 mm.

The prepreg can be produced by, for example, impregnating a substrate with a resin composition containing an organic solvent and removing the organic solvent. The impregnated resin composition may be semi-cured by heating.

The prepreg is suitable for a semiconductor package and a printed wiring board which require high thermal conductivity.

### [Cured Product of Prepreg or Laminate Thereof]

A cured product of the prepreg or the laminate thereof can be produced by heating and pressurizing a prepreg or one or more prepregs stacked. The number of laminated prepregs is not particularly limited, and is, for example, 2 to 20. Examples of the apparatus for heating and pressurizing include a multistage press, a multistage vacuum press, a continuous molding machine, and an autoclave molding machine. The conditions of heating and pressurization may be selected according to the thermosetting resin, the curing agent, and the like to be used. For example, the temperature is from 100 to 250° C., the pressure is from 0.2 to 10 MPa, and the time is from 0.1 to 5 hours.

### [Metal-Clad Laminate]

A metal-clad laminate of one embodiment includes a cured product of the prepreg or the laminate thereof, and a metal foil disposed on at least one main surface of the cured product. The metal-clad laminate can be produced by, for example, stacking 1 to 20 prepregs, and heating and pressurizing the prepregs in a state where a metal foil is disposed on one surface or both surfaces of the prepregs. The apparatus for heating and pressurizing and the conditions of heating and pressurizing are the same as described above. The metal foil is not particularly limited as long as it is used for electronic components. Examples of the metal foil include a copper foil and an aluminum foil.

### [Electronic Component Device]

An electronic component device of one embodiment includes an element and a cured product of the resin composition sealing the element. Examples of the element include active elements such as a semiconductor chip, a transistor, a diode, and a thyristor; and passive elements such as a capacitor, a resistor, and a coil.

Examples of the electronic component device include a device obtained by sealing an element portion, which is obtained by mounting an element on a support member such as a lead frame, a wired tape carrier, a wiring board, glass, a silicon wafer, or an organic substrate, with a resin composition. More specifically, examples thereof include general resin-sealed ICs such as a dual inline package (DIP), a plastic leaded chip carrier (PLCC), a quad flat package (QFP), a small outline package (SOP), a small outline J-lead package (SOJ), a thin small outline package (TSOP), and a thin quad flat package (TQFP) having a structure in which an element is fixed on a lead frame, a terminal portion of the element such as a bonding pad and a lead portion are connected by wire bonding, a bump, or the like, and then the element is sealed by transfer molding or the like using a resin composition; a tape carrier package (TCP) having a structure in which an element connected to a tape carrier by a bump is sealed with a resin composition; a chip on board (COB) module, a hybrid IC, and a multi-chip module having a structure in which an element connected to a wiring formed on a support member by wire bonding, flip chip bonding, solder, or the like is sealed with a resin composition; a ball grid array (BGA), a chip size package (CSP), and a multi-chip package (MCP) having a structure in which an element is mounted on a surface of a support member having a terminal for wiring board connection formed on a rear surface, the element and a wiring formed on the support member are connected by bump or wire bonding, and then the element is sealed with a resin composition.

Examples of the method for sealing an electronic component device using the resin composition include a low-pressure transfer molding method, an injection molding method, and a compression molding method. Among these, the low-pressure transfer molding method is generally used.

### EXAMPLES

Hereinafter, the present invention will be described more specifically with reference to Examples and Comparative Examples, but the present invention is not limited to the following Examples.

### <Evaluation Method>

### (D10, D50, and D90)

The 40 mg of the sample was put into 50 mL of water to which two drops of a nonionic surfactant (TRITON (trade name)-X; Roche Applied Science) were added, and the sample was dispersed by ultrasonic waves for 3 minutes. The dispersion was measured using a laser diffraction-scattering particle size analyzer (MicrotracBEL Corp., MT3300II). The 10% particle size, 50% particle size, and 90% particle size in the obtained volume-based cumulative particle size distributions were determined as the D10, D50, and D90, respectively.

### (α-Phase Percentage)

The α-phase percentage was calculated from the relationship of α-phase percentage (%)=(X/(X+Y))×100, wherein X is the maximum peak intensity at a diffraction angle 2θ=35.2°±0.2° of the α-alumina crystal phase in X-ray diffraction measurement, and Y is the maximum peak intensity at a diffraction angle 2θ=67.3°±0.2° of the crystal phase other than α-alumina. The X-ray diffraction measurement of the alumina powder was performed using an X-ray diffractometer PW3040/60X′ Pert-MRD (Malvern Panalytical), using copper as an X-ray tube, under conditions of a tube voltage 45 kV and a tube current 40 mA.

### (BET Specific Surface Area A)

The BET specific surface area A was measured and calculated according to “6.2 Flow method (3.5), Single point method” in JIS R 1626:1996 (Measuring method for the specific surface area of fine ceramic powders by gas adsorption using the BET method). Specifically, about 2 g of a sample was weighed and taken, and subjected to a preliminary degassing treatment at 180° C. for 20 minutes. Thereafter, the sample was mounted in an automatic specific surface area measuring apparatus (Mountech Co., Ltd., Macsorb), the amount of nitrogen gas adsorption was measured using pure nitrogen and a nitrogen-helium mixed gas (mixing ratio:nitrogen 30 mol %, He 70 mol %), and the BET specific surface area A was calculated by Single point method.

(Sphere-Equivalent Specific Surface Area Sa Calculated from Particle Size Distribution)

The sphere-equivalent specific surface area (Sa) was calculated according to the following equation based on the data of the particle size distribution obtained using a laser diffraction-scattering particle size analyzer (MicrotracBEL Corp., MT3300II). The method of preparing the sample is the same as the preparation method in the measurement of D10, D50, and D90.

$$Sa = \frac{6 \sum \frac{{V}_{i}}{{d}_{i}}}{ρ \sum {V}_{i}} \qquad [ Math . 1 ]$$

dᵢ represents the average diameter in the particle size class i, Vᵢ represents the relative volume of the particle size class i, and p represents the specific gravity. As ρ, a specific gravity calculated by the following method is used.

### (Specific Gravity)

The 5 mg of the sample was placed in a sample cell for measurement, and the specific gravity was measured by a gas (helium) replacement method using a gas pycnometer (Shimadzu Corporation, product name: AccuPyc II 1340). Specifically, the sample cell for measurement was installed in the gas pycnometer, the atmosphere was replaced with helium gas to determine the volume of the sample, and the specific gravity was calculated by dividing the mass of the sample by the volume.

### (Circularity)

The circularity is an average value of values calculated by the following Equation (3) for 2000 or more particles, wherein S is an area of a particle projection and L is a perimeter of the particle projection.

$$( 4 \times π \times S ) / {L}^{2} ; \qquad Equation ( 3 )$$

The area S and the perimeter L were measured using FPIA-3000 (Malvern Panalytical). As a pre-treatment, in view of the measuring range of the device, about 10 g of the sample was put into a metal sieve having a pore size of 25 μm with a diameter of 200 mm, and particles larger than 25 μm were removed with shower water. The sample under the sieve was transferred to a plastic container and used as a measurement sample. The measurement conditions were LPF/HPF standard (20× lens) and bright field, and Particle Sheath (Malvern Panalytical) was used as a measurement solvent. A measurement sample was weighed in a 50 ml beaker by 2 g so that the number of effective particles was 2000 or more and the ratio of the number of effective particles/the total number of particles was 55 to 70%, 50 mL pure water was added thereto, and the sample was dispersed for 3 minutes by an ultrasonic disperser in 200 W, and then the mixture was put in the apparatus and measured. As data processing after the measurement, data having plurality of grains on one screen was deleted, and the circularity was calculated.

### (Oil Absorption Percentage)

The 10 g of the sample was placed in a mortar having a diameter of 10 cm, and a small amount of liquid epoxy was added dropwise thereto and mixed well with the sample. The dropping of the small amount of the resin was repeated until the sample and the epoxy resin became a lump. The volume of the dropped resin was calculated from the weight of the resin at the time when the sample and the resin became a lump, and the oil absorption percentage was calculated by the following equation. The volume of the sample was calculated from the specific gravity measured above.

$$Oil absorption percentage ( \% ) = ( volume of dropped resin / ( volume of sample + volume of dropped re sin ) ) \times 100$$

### (Thermal Conductivity)

An alumina powder was mixed with a resin for an epoxy mold compound containing an epoxy resin, a polyfunctional phenol compound as a curing agent, and an organophosphorus compound as a curing accelerator at a volume filling percentage % shown in Table 1, and the mixture was diluted with methyl ethyl ketone and then agitated using a mix rotor to prepare a varnish having a solid content concentration of 75 mass %. The obtained varnish was applied onto a release PET film to a thickness of 200 μm, dried at a temperature of 110° C. for 10 minutes, and then the dried resin composition was pulverized. In order to mold a composite for measurement using the pulverized resin composition, the pressing pressure was increased to 10 kN while the composition was held at a heating temperature of 80° C. for 3 minutes in a heated vacuum press machine. When the pressing pressure reached 10 kN, the temperature was raised to 160° C. at a rate of 20° C./3 minutes, and when the heating temperature reached 100° C., the pressing pressure was raised from 10 kN to 40 kN. When the heating temperature reached 160° C., the temperature was maintained for 16 minutes to prepare a resin composite having a thickness of 1 mm. The resin composite was post-cured at 175° C. for 6 hours to obtain a composite for measurement. The thermal conductivity was measured using the composite for measurement.

The thermal conductivity is calculated by the product of the thermal diffusivity, the low-pressure specific heat capacity, and the density. The thermal diffusivity was measured using a xenon flash analyzer (NETZSCH JAPAN Co., Ltd., LFA647 HyperFlash). The specific heat capacity at constant pressure was calculated from the specific heat capacity of each material and the blending ratio thereof. The density was measured using an electronic densitometer (Alfa Mirage Co., Ltd., MDS-3000). The thermal conductivity was calculated from the product of these. The thermal diffusivity and density were measured at 23° C., and the specific heat capacity at 25° C. was used as the value of the specific heat capacity at constant pressure.

### Comparative Example 1

The raw alumina powder (D50:1.8 μm) was charged into a high-temperature region of 2200° C. formed in the furnace by flames formed by LPG and oxygen and subjected to spheroidizing treatment. The spherical alumina powder before heat treatment was charged into cooling washing water at 80° C. in a water tank within 5 seconds after leaving the furnace, and was cooled and washed. The slurry containing the obtained spherical alumina powder before heat treatment was separated into a high-concentration slurry and a supernatant in the recovery step, and the high-concentration slurry was dried in a dryer at an atmospheric temperature of 180° C. in an air atmosphere in the drying step to obtain a spherical alumina powder 1 before heat treatment.

### Comparative Example 2

The raw alumina powder (D50:1.2 μm) was charged into a high-temperature region of 2200° C. formed in the furnace by flames formed by LPG and oxygen and subjected to spheroidizing treatment. The spherical alumina powder before heat treatment was charged into cooling washing water at 80° C. in a water tank within 5 seconds after leaving the furnace, and was cooled and washed. The slurry containing the obtained spherical alumina powder before heat treatment was separated into a high-concentration slurry and a supernatant in the recovery step, and the high-concentration slurry was dried in a dryer at an atmospheric temperature of 180° C. in an air atmosphere in the drying step to obtain a spherical alumina powder 2 before heat treatment.

### Comparative Example 3

Advanced Alumina AA-2, Sumitomo Chemical Co., Ltd.

### Example 1

The spherical alumina powder 1 before heat treatment was heat-treated in a muffle furnace in an air atmosphere at a temperature of 1250° C. for 4 hours. After cooling, the mixture was subjected to a crushing treatment using a wet shear disintegrator Nanomizer, and then to dispersion and classification treatments using a high-speed rotating thin-film classifier Filmix, to obtain a spherical alumina powder.

### Example 2

The spherical alumina powder 2 before heat treatment was heat-treated in a muffle furnace in an air atmosphere at a temperature of 1250° C. for 4 hours. After cooling, the mixture was subjected to disintegration and classification treatments using a swirling flow jet mill to obtain a spherical alumina powder.

TABLE 1

| | | | | | | | | Specific | | | | | | |
|---|---|---|---|---|---|---|---|---|---|---|---|---|---|---|
| | Heat | | | | | | | surface area | | | | | Filling | |
| | treat- | Heat | | | | | BET | Sa calculated | Particle | | | Oil | percentage | Thermal |
| | ment | treat- | | | | α- | specific | from particle | surface | | | Absorp- | in resin | conduc- |
| | temper- | ment | | | | Phase | surface | size | roughness | Specific | Circu- | tion | composi- | tivity |
| | ature | time | D10 | D50 | D90 | Percent- | area A | distribution | A/Sa | gravity | larity | Percent- | tion | (W/m · |
| | (° C.) | (Hr) | (μm) | (μm) | (μm) | age (%) | (m²/g) | (m²/g) | (—) | (g/cm³) | (—) | age (%) | (vol %) | K) |
| Example 1 | 1250 | 4 | 0.6 | 1.6 | 3.2 | 96 | 1.37 | 1.17 | 1.17 | 3.88 | 0.96 | 36.8 | 60 | 2.1 |
| Example 2 | 1250 | 4 | 0.7 | 1.5 | 2.2 | 97 | 1.46 | 1.14 | 1.28 | 3.94 | 0.96 | 42.2 | 60 | 1.9 |
| Comparative | — | — | 0.7 | 2.1 | 4.4 | 50 | 1.06 | 1.03 | 1.03 | 3.73 | 0.96 | 31.7 | 60 | 0.9 |
| Example 1 | | | | | | | | | | | | | | |
| Comparative | — | — | 0.6 | 1.3 | 2.1 | 46 | 1.56 | 1.41 | 1.10 | 3.72 | 0.96 | 37.5 | 60 | 1.1 |
| Example 2 | | | | | | | | | | | | | | |
| Comparative | — | — | 2.0 | 2.7 | 3.9 | 99 | 0.90 | 0.64 | 1.41 | 4.01 | 0.95 | — | 60 | 1.3 |
| Example 3 | | | | | | | | | | | | | | |

As shown in Table 1, the thermal conductivities of the resin compositions containing the heat-treated spherical alumina powders of Examples 1 and 2 were 2.1 W/m·K and 1.9 W/m·K, respectively. It can be seen that these exhibit better thermal conductivity than the resin compositions containing the spherical alumina powders before heat treatment of Comparative Examples 1 and 2. On the other hand, the non-spherical alumina of Comparative Example 3, although not subjected to heat treatment, had a high α-phase percentage, and it is presumed that the thermal conductivity of the non-spherical alumina itself is high. However, the thermal conductivity of the resin composition containing the non-spherical alumina of Comparative Example 3 was lower than those of Examples 1 and 2. This is considered to be because the particle surface roughness of the non-spherical alumina is too high and the filling properties is poor. Specifically, it is presumed that contact points of the particles, which become a heat conduction path, are not uniformly and sufficiently formed due to the poor filling properties.

### REFERENCE SIGNS LIST

1 hopper
2 spheroidizing burner
3 water-cooled jacket-type spheroidizing furnace
4 agitated cooling tank
5 separation tank
6 drying device
7 cooling water pump
8 scrubber-type collection device
9 exhaust device
10 shower

1. A spherical alumina powder, wherein
D50 is 0.1 to 40 μm;
a circularity is 0.90 or more and 1.00 or less;
an α-phase percentage is 60% or more and 100% or less; and
a particle surface roughness represented by Equation (1) below is 1.14 or more and 1.35 or less:
$$Particle surface roughness = BET specific surface area A / sphere - equivalent specific surface area Sa calculated from particle size distribution . \qquad Equation ( 1 )$$

2. The spherical alumina powder according to claim 1, wherein a specific gravity is 3.80 g/cm³ or more.

3. The spherical alumina powder according to claim 1, wherein a BET specific surface area A is 0.1 or more and 2.0 or less.

4. The spherical alumina powder according to claim 1, wherein an oil absorption percentage is 30% or more and 50% or less.

5. A resin composition comprising the spherical alumina powder according to claim 1 and a resin.

6. A prepreg comprising a substrate impregnated with the resin composition according to claim 5.

7. A cured product of the prepreg according to claim 6 or a laminate thereof.

8. A metal-clad laminate comprising:
the cured product according to claim 7; and
a metal foil disposed on at least one main surface of the cured product.

9. The resin composition according to claim 5, which is used as a sealing material for an electronic component device.

10. An electronic component device comprising an element and a cured product of the resin composition according to claim 5, the cured product sealing the element.

11. A method for producing a spherical alumina powder, comprising:
a high-temperature step of forming a high-temperature region inside a furnace with a burner that forms a flame;
a spheroidizing step of charging a raw material alumina powder into the furnace and heating and melting the raw material alumina powder to produce a spherical alumina powder before heat treatment;
a cooling and washing step of charging the spherical alumina powder before heat treatment into cooling washing water in a water tank to cool and wash the spherical alumina powder before heat treatment;
a recovery step of separating the spherical alumina powder before heat treatment and the cooling washing water from each other to recover the spherical alumina powder before heat treatment; and
a heat treatment step of heat-treating the recovered spherical alumina powder before heat treatment at 1100 to 1300° C. in an air atmosphere to obtain a spherical alumina powder.
